(19) United States
(12) Patent Application Publication
(10) Pub. No.: US 2026/0164579 A1
(43) Pub. Date: Jun. 11, 2026

(54) COVERS AND KEYPAD OVERLAYS FOR HANDHELD DEVICE DATA ENTRY

(71) Applicant: Micount LLC, Indianapolis, IN (US)

(72) Inventor: Michael Edward McCarthy, III, McCordsville, IN (US)

(21) Appl. No.: 18/969,599

(22) Filed: Dec. 5, 2024

(51) Int. Cl. H05K 5/03; H05K 5/00

(52) U.S. Cl. CPC H05K 5/03; H05K 5/0018

(57) ABSTRACT

The present invention involves cases and overlays for an electronic device used for data entry. The case comprises a cover portion and an overlay portion having one or more actuatable keys for interacting with an enclosed electronic device wirelessly. The overlay portion includes one or more openings which allows a user to directly contact the enclosed device. Interchangeable overlays are also disclosed allowing for different combinations and configurations of keys and/or openings depending on the electronic device being used and the desired task being performed and the associated software.

### CROSS-REFERENCE TO RELATED APPLICATIONS

This application is related to and improves upon the innovations disclosed in U.S. Patent Publication 2016/0378226, which was published on Dec. 29, 2016, the disclosures of which are incorporated herein by reference.

### BACKGROUND OF THE INVENTION

### Field Of The Invention

The field of the invention is that of cases and covers for hand held electronic devices. More particularly, the invention deals with such cases and covers for devices having touch sensitive screens.

### Description of the Related Art

Handheld computing devices are commonly used in commercial and industrial settings. These devices now have sufficient computing power and memory to perform a wide variety of tasks such as recording instrument readings, inventory and other data entry, displaying repair or instruction manuals, and the like. The ability to access data networks wirelessly allows these tasks to be performed in real time in addition to being able to record data for output to a computer and/or network at a later time.

As useful as handheld computing devices can be they have serious limitations and drawbacks when used for commercial and/or industrial applications. Such environments are typically dirty and contamination from dust, grime, and other detritus can severely shorten the life of sensitive electronics. Such devices typically rely on users touching the face of the device directly to interact with it, often with touch sensitive screens. In industrial settings, workers will commonly have very dirty hands which may damage the screen of the device or cause input errors.

Covers for such devices are typically intended for office settings and so are insufficient to protect the devices in the harsher conditions of an industrial setting. Simply increasing the weight and/or thickness of such covers may provide additional protection but at the cost of interactivity with the device. Additionally, the touch screens of these devices provide no tactile feedback to users which forces the user to repeatedly look at the device to ensure the correct information is being entered.

### SUMMARY

Embodiments of the present invention involve a case for a handheld electronic device having a touch sensitive screen. The case has a cover portion and an overlay portion defining a device cavity when the cover portion is engaged with the overlay portion. The case also has a component for data entry that avoids the manual activation of the screen by wirelessly transmitting the data entry for rote numerical counting applications while allowing access to other features using the touch sensitive screen.

In one embodiment, the mechanism for data entry includes a keypad allowing the touch of a human hand to actuate the data entry without activating the touch sensitive screen. The keypad is associated with an overlay cover of the touch sensitive screen.

In some embodiments, the overlay portion further comprises at least one cutout portion sized and configured so as to allow a user to directly contact an electronic device disposed within the device cavity.

In some embodiments, at least a portion of the overlay portion is clear, in others opaque.

In several embodiments, the cover portion further includes at least one clear port.

Further embodiments have the cover portion further including at least one cut out portion. Other embodiments are configured so that the device cavity is waterproof when the cover portion is engaged with the overlay portion.

### BRIEF DESCRIPTION OF THE DRAWINGS

The above mentioned and other features and objects of this invention, and the manner of attaining them, will become more apparent and the invention itself will be better understood by reference to the following description of an embodiment of the invention taken in conjunction with the accompanying drawings, wherein:

FIG. 1 is a top plan view of a keypad and associated overlay positioned in a case according to one embodiment of the disclosed invention.

FIG. 2 is a side view of the embodiment shown in FIG. 1.

FIG. 3 is a side view of the embodiment shown in FIG. 1, taken from the side opposite that of FIG. 2.

FIG. 4 is front side view of the embodiment shown in FIG. 1.

FIG. 5 is back side view of the embodiment shown in FIG. 1.

FIG. 6 is a bottom plan view of the embodiment shown in FIG. 1.

FIG. 7 is an exploded view of the embodiment shown in FIG. 1.

FIG. 8 is a perspective view of the embodiment of FIG. 1 in use.

Corresponding reference characters indicate corresponding parts throughout the several views. Although the drawings represent embodiments of the present invention, the drawings are not necessarily to scale and certain features may be exaggerated in order to better illustrate and explain the present invention. The exemplification set out herein illustrates an embodiment of the invention, in one form, and such exemplifications are not to be construed as limiting the scope of the invention in any manner.

### DESCRIPTION OF EMBODIMENTS OF THE PRESENT INVENTION

The embodiments disclosed below is/are not intended to be exhaustive or limit the invention to the precise form disclosed in the following detailed description. Rather, the embodiment is chosen and described so that others skilled in the art may utilize its teachings.

For the purposes of promoting an understanding of the principles of the claimed technology and presenting its currently understood best mode of operation, reference will now be made to the embodiments illustrated in the drawings and specific language will be used to describe the same. It will nevertheless be understood that no limitation of the scope of the claimed technology is thereby intended, with such alterations and further modifications in the illustrated device and such further applications of the principles of the claimed technology as illustrated therein being contemplated as would normally occur to one skilled in the art to which the claimed technology relates.

The present application discloses a cover, keypad, and/or overlay devices which is used in combination with a variety of different hand held computing devices. Such mobile devices may include, but are not limited to tablet computers, smartphones, calculators, smart card readers, personal digital assistants, portable media devices, digital cameras, and the like. The mobile devices may also include purpose-built and/or industry specific handheld devices. The cover and overlay devices disclosed herein may be sized and configured for use with a variety of different electronic devices, and is further configured in conjunction with displays created by software running within the electronic devices.

In embodiments, the electronic device includes a touch sensitive screen or touchscreen, that is a screen that functions as an input device recognizing the touch of a human finger, for example without limitation, through changes in sonic pressure, electrical resistance, capacitive resistance, and/or visual or infrared interference of a human finger, glove, or stylus touching a particular portion of the screen. In such embodiments, software for the electronic device may display an input device, such as a numerical keypad or a character-based keypad. The software is configured to respond to input on specific sections of the screen to correspond to the numerical or character displayed on the screen. For the sake of simplicity, the following description of embodiments relates to numerical keypads in a conventional arrangement as a 4 by 3 matrix with two of the lower corner sections representing special characters rather than numbers. However, the principles of the invention may be applied to qwerty keypads or other configurations of input devices that are either physically incorporated into a handheld device, or which are displayed upon the touchscreen. Similarly, while the disclosed embodiments contemplate accommodating input areas for sliding with a scroll bar or similar input mechanism, such additional input areas are completely optional and the device may fully perform without such input areas. However, the unique combination of the touch responsive keypad for fast data entry without interacting with the touch screen, e.g. in inventory counting applications, with the ability to access touchscreen features when needed, provides an inventive tool for inventory control. Thus, the embodiment disclosed below address a specific need in the area of numeric keypad entry, but no limitations or specific input needs are intended by the following exemplary and illustrative embodiments.

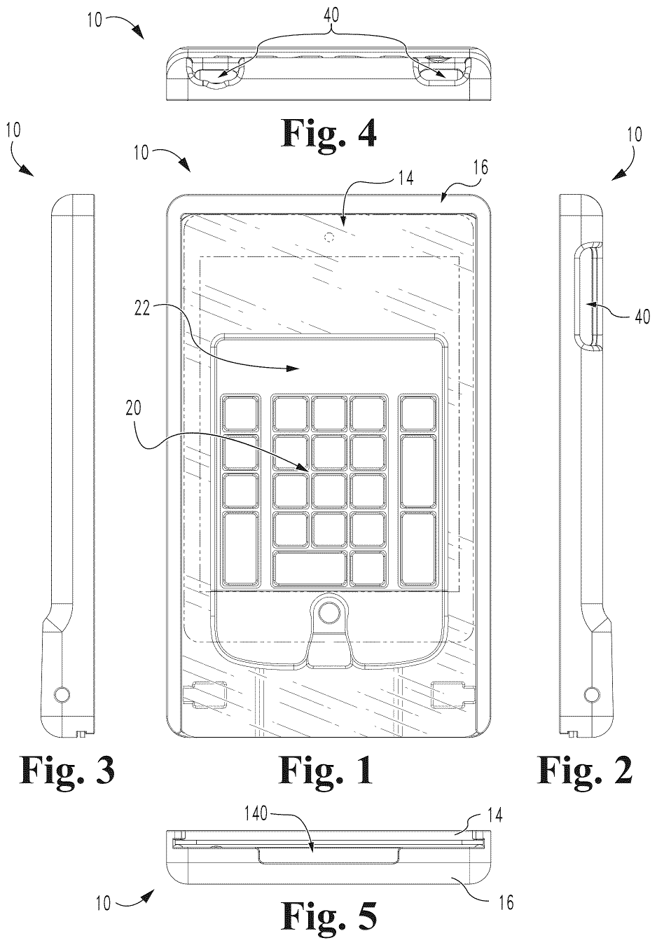

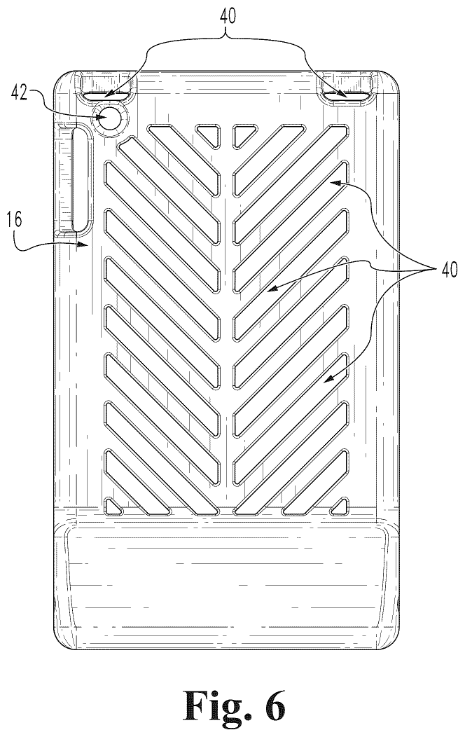

One embodiment of a keypad input device overlay and case or cover 10 is shown in FIGS. 1-7 which may be configured so as to work with a variety of handheld electronic devices, for example without limitation a tablet such as an iPad® tablet (iPad is a registered trademark of Apple Corporation, Cupertino, California) or a Galaxy® tablet (Galaxy is a registered trademark of Samsung Corporation of the Republic of Korea). In this particular example, device 10 comprises input overlay portion 14 and back cover portion 16. When engaged with each other the overlay portion and back cover portion define cavity 140 for holding an electronic device. The exact size and shape of device cavity 140 may vary as desired, particularly to confine a particular device so that the touchscreen display is precisely oriented. Optionally, spacers, clips, brackets, and the like may be used to hold electronic devices of different sizes and shapes in place when they are disposed within the device cavity.

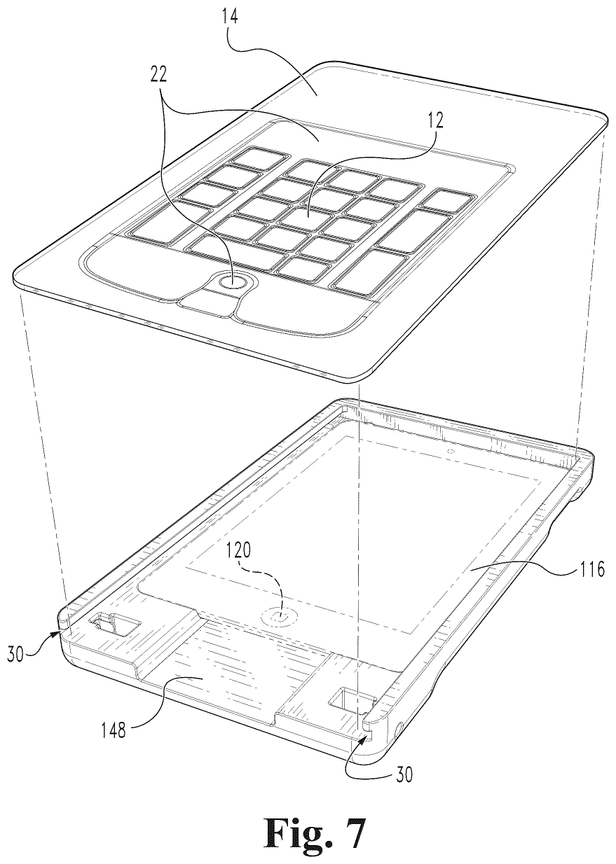

Overlay portion 14 includes keypad 20 having a plurality of tactile responsive keys 12 which are mounted upon, or alternatively co-planarly located with, overlay portion 14. Keys 12 are designed to be actuated by pressing down on outer surfaces of keys 12 such that there is mechanical resistance while wirelessly activating the appropriate location on the engaged computing device, or alternatively working with software that only requires a wireless transmission of keypad entries. When released, a spring or other biasing member (not shown) provides a tactile response to the presser. Overlay 14 includes one or more cutouts 22 so that engaged device 116 (shown in dashed lines in FIG. 7) may be contacted directly by a user in one or more locations, for example, to physically engage switch or button 120 located on device 116 or gap 148 in cavity 140 so as to allow an auxiliary device into an access port or jack (not shown) of device 116.

Cover portion 16 includes slot 30 for receiving overlay portion 14. Keys 12 are disposed sufficiently away from edges of overlay portion 14 to allow overlay portion 14 to slide into slot 30 once device 116 is positioned within cavity 140 so as to retain device 116 regardless of orientation. By virtue of cutouts 22, the user may access the touchscreen of device 166 if desired. Further, if a plug or other physical connection is required with device 116 while in cover portion 16, such plug or connection may access device 116 through gap 148.

The overlay may have more keys or cutouts as desired. Optionally, different overlays may be interchanged with the cover depending on the task being performed, or the display screen presented by various software (not shown). For example, in one embodiment, only one screen button is needed to the data entry to be completed. In other embodiments, further screen selections may be desired to adequately categorize the counting data. Optionally, the keys and software may be configured so as to provide an audible feedback such as a click when actuated.

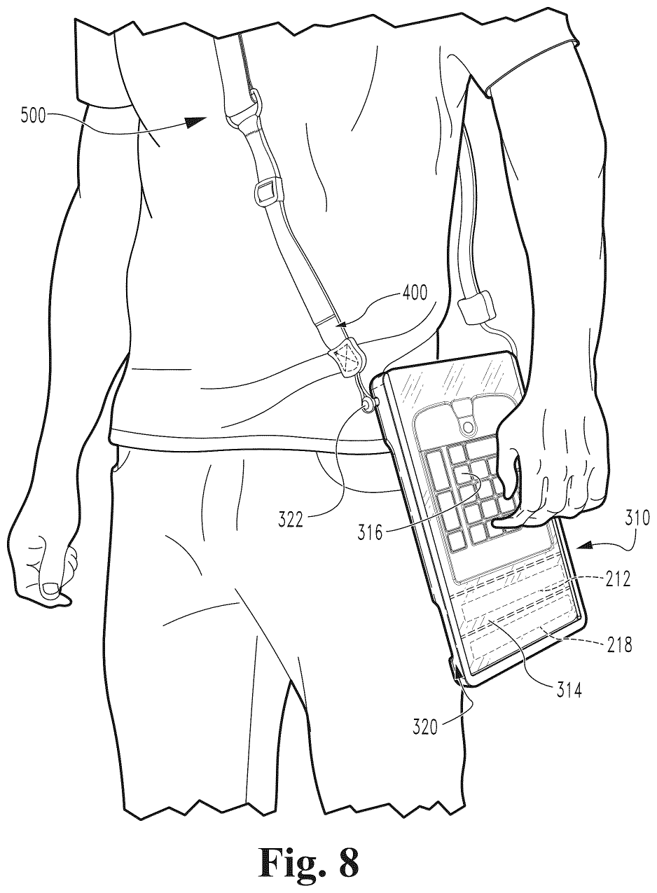

In this illustrative embodiment, overlay portion 14 is made from a clear plastic material. In other examples, the overlay may be made from a tinted or opaque material so as to protect the enclosed electronic device from ultraviolet light or other potentially harmful radiation. In the example shown in FIG. 8, overlay 214 may have one portion that is clear 212 so that the enclosed device may be viewed therethrough and another portion 218 that is opaque or tinted so that parts of the device which do not need to be viewed are protected. Further, overlay portion may have two or more components, for example without limitation, embodiments where portions 212 and 218 are separate from keypad 12, and may have shapes and configurations that are adapted to software displays on device 116. Such shapes and configurations may be additional shaded or cutout portions to coordinate with the software of device 116.

Back cover portion 16 of device 10 may be made from a hard plastic, rubberized or soft plastic, composite, or other suitable material. Optionally, portions of back cover portion 16 may be padded or cushioned to reduce potential damage to the enclosed device from dropping. Additionally, the outer surface of the cover may include raised portions and/or non-slip portions so as to enhance a user's grip on the device such as when a user is wearing protective gloves or working in wet conditions.

Optionally case 10 may include one or more cutouts 40 to reduce the weight of device 10 or to increase ventilation, or to allow access to parts of the enclosed device (for switches, ports, interfaces, buttons, and the like). For example, cutouts 40 may be configured to allow connecting an auxiliary device such as a scanning wand or printer to the enclosed device. In other embodiments, cover portion 16 has no openings so as to better protect the enclosed electronic device. In some embodiments, cover portion 16 includes one or more clear ports 42 for allowing the use of cameras, IR scanners, and other features of the enclosed device to be used, for example without limitation to allow the scanning of bar codes and the like as part of the counting process.

Back cover portion 16 and/or overlay portion 14 may be made from a material which allows passage of wireless signals through device 10 so as to allow the enclosed electronic device to be used with suitable wireless networks, wireless devices, IR controllers, and the like. In other examples, the cover and overlay are made from materials which block one or more wireless signals so as to prevent the enclosed device from being accessed wirelessly for security purposes, as well as the keypad of keys 22 having shielding so that the wireless data entry is only accessible to device 116 within cover portion 16 and not to devices outside. In such examples enclosed device 116 may need to be removed from the cover or physically connected using a wire or cable to be accessed by an outside device or computer.

FIG. 8 shows device cover 310 according to an embodiment of the disclosed invention. In this particular example, device case or cover 310 comprises back cover portion 320, front cover portion 312, and insert portion 314. Insert portion 314 is optionally separable and removable from front cover portion 312. Insert portion 314 includes one or more movable keypads 316 which are sized and positioned so as to interact wirelessly with the enclosed electronic device (hidden withing cover portions 312, 314 and 320) when depressed. Individual keypads 316 may be round, square, rectangular, or any other desired shape. Keypads of more than one shape may be incorporated into a particular insert as desired.

The inert portion is removable in some examples so as to allow the insert to be swapped out as desired. The insert may be removed and replaced with an insert having a different configuration of keypads and/or cut outs or replaced by an identical insert when the original insert becomes worn or broken, or when using another software program some screen access is desired. Swapping out different inserts may be desired to perform different functions with the same electronic device, for example if different keys or buttons are needed for a particular job, or a particular software program creating the images on the touchscreen. Additionally, different inserts may be desired for use with different electronic devices and/or software. Further, cover portion 316 has attachment portions 322 configured for allowing attachment of strap 400 so that the combination device case and electronic device may be worn by user 500 (FIG. 8).

While the claimed technology has been illustrated and described in detail in the drawings and foregoing description, the same is to be considered as illustrative and not restrictive in character. It is understood that the embodiments have been shown and described in the foregoing specification in satisfaction of the best mode and enablement requirements. It is understood that one of ordinary skill in the art could readily make a nigh-infinite number of insubstantial changes and modifications to the above-described embodiments and that it would be impractical to attempt to describe all such embodiment variations in the present specification. Accordingly, it is understood that all changes and modifications that come within the spirit of the claimed technology are desired to be protected.

While this invention has been described as having an exemplary design, the present invention may be further modified within the spirit and scope of this disclosure. This application is therefore intended to cover any variations, uses, or adaptations of the invention using its general principles. Further, this application is intended to cover such departures from the present disclosure as come within known or customary practice in the art to which this invention pertains.

What is claimed is:

1. A case for a electronic device having a touch sensitive screen, the case comprising:
a cover portion;
an overlay portion;
a device cavity defined by the cover portion engaged with the overlay portion, which is sized and configured to hold an electronic device having a touchscreen; and
at least one of the cover and overlay portions having a keypad with a plurality of keypads, each of the keypads being configured to wirelessly transmit keypad entry to the electronic device, the at least one of the cover and overlay portions having a cutout allowing access to the touchscreen.

2. The case of claim 1 wherein the overlay portion further comprises at least one cutout portion sized and configured so as to allow a user to directly contact a touchscreen of an electronic device disposed within the device cavity.

3. The case of claim 1 wherein at least one keypad provides a tactile response to actuation.

4. The case of claim 1 wherein at least a portion of the overlay portion is clear.

5. The case of claim 1 wherein at least a portion of the overlay portion is opaque.

6. The case of claim 1 wherein the cover portion further includes at least one access gap.

7. The case of claim 1 wherein the cover portion further includes at least one cut out portion.

8. The case of claim 1 wherein the device cavity is waterproof when the cover portion is engaged with the overlay portion.

9. The case of claim 1 further comprising a strap, wherein the cover portion includes means for attaching to the strap.

10. A case for an electronic device having a touch sensitive screen, the case comprising:
a cover portion;
a overlay portion having a removable insert;
a device cavity defined between the cover portion and the overlay portion, which is sized and configured to hold an electronic device having a touchscreen;
wherein the removable insert includes a keypad having a plurality of keypads capable of wirelessly transmitting activated keys to an electronic device disposed within the device cavity, wherein the overlay portion includes a cutout allowing access to the device cavity and any touchscreen disposed therein.

11. The case of claim 10 wherein at least one of the keypads is configured to provide a tactile response to actuation.

12. The case of claim 10 wherein the overlay portion further comprises at least one cutout portion sized and configured so as to allow a user to directly contact the touch sensitive screen of the electronic device disposed within the device cavity.

13. The case of claim 10 wherein at least a portion of the overlay portion is clear.

14. The case of claim 10 wherein at least a portion of the overlay portion is opaque.

15. The case of claim 10 wherein the cover portion further includes at least one clear port.

16. The case of claim 10 wherein the cover portion further includes at least one cut out portion.

17. The case of claim 10 wherein the device cavity is waterproof when the cover portion is engaged with the overlay portion.

18. In combination, an electronic device with a touchscreen and a cover, the cover including a base portion and an overlay portion defining a device cavity housing the electronic device, the overlay portion having a keypad with a plurality of keypads, the electronic device having software which when executed provides for wireless entry of keypad entries, the software further configured to receive instructions through interaction with the touchscreen, the overlay portion being configured to have at least one cutout allowing access to the touchscreen.

19. The case of claim 18 wherein:
at least one of the keypads is configured to provide a tactile response to actuation;
the overlay portion further comprises at least one cutout portion sized and configured so as to allow a user to directly contact the touch sensitive screen of the electronic device disposed within the device cavity;
at least a portion of the overlay portion is clear;
at least a portion of the overlay portion is opaque;
the cover portion further includes at least one clear port; and
device cavity is waterproof when the cover portion is engaged with the overlay portion.
